(19) United States
(12) Patent Application Publication
(10) Pub. No.: US 2026/0013404 A1
(43) Pub. Date: Jan. 8, 2026

(54) SUPERCONDUCTING DIODE

(71) Applicant: VICTORIA LINK LIMITED, Wellington (NZ)

(72) Inventors: Rodney Alan Badcock, Wellington (NZ); Justin Brooks, Wellington (NZ); Christopher William Bumby, Wellington (NZ); Ratu Mataira-Cole, Wellington (NZ)

(73) Assignee: VICTORIA LINK LIMITED, Wellington (NZ)

(21) Appl. No.: 18/992,321

(22) PCT Filed: Jul. 11, 2023
(86) PCT No.: PCT/IB2023/057123

§ 371 Date: Jan. 8, 2025

(30) Foreign Application Priority Data
Jul. 14, 2022 (AU) 2022901971

(51) Int. Cl. H10N 60/84

(52) U.S. Cl. CPC H10N 60/84

(57) ABSTRACT

The technology relates to electrical devices comprising a length of superconducting material with a critical current when current travels in one direction is different to a critical current of the length of superconducting material when current travels through the length of superconducting material in an opposite direction. The electrical device may further comprise a magnetic field generator comprising two permanent magnets positioned on the same side of the length of superconducting material and arranged substantially anti-parallel to each other. The polar axes of the two permanent magnets may be oriented substantially perpendicular to the faces of the length of superconducting material.

### 1. FIELD OF INVENTION

The present technology relates to superconducting power supplies. The present technology particularly relates to electrical devices comprising components formed from superconducting materials, especially high-temperature superconducting materials. The present technology particularly relates to electrical devices that act as, or analogously to, diodes.

### 2. BACKGROUND TO THE INVENTION

Superconducting circuits have a wide range of applications. Examples of applications for systems including superconducting circuits include (and are not limited to): superconducting magnets; flux pumps; fault current limiters; magnetic energy storage systems; space propulsion; nuclear fusion; nuclear magnetic resonance (NMR); magnetic resonance imaging (MRI); levitation; water purification and induction heating.

Many applications including superconducting circuits require low-voltage high-current power supplies, for example in strong high temperature superconducting (HTS) magnets for applications such as fusion. To meet these requirements, traditional power supplies require a large amount of space resulting in a large infrastructure challenge. Also, connecting a normal conducting circuit to a superconducting circuit housed in a cryostat introduces a large thermal load through the physical contacts into the cryostat, creating a cooling challenge. This requires sophisticated thermal design and imposes a considerable heat penalty on the cryostat and cooling system. It also incurs a significant voltage drop across the normal conducting circuit components, necessitating a significantly higher-power supply than required solely to energise the superconducting coil.

Superconducting power supplies help address these issues. Higher current densities allow the power supply to be more compact, and the ability to magnetically couple alternating current (AC) circuits without any physical contact using HTS flux pumps circumvents the cooling issue. However, in order to power a HTS magnet, a large direct current (DC) is needed, requiring rectification to convert the AC (a current which periodically reverses in direction) into DC (a current which flows only in one direction). Other applications of superconducting circuits also require, or benefit from, rectifying a current. Semi-conducting diodes may be used to rectify AC into DC. A diode is a component which allows current to flow with low resistance in one direction, but offers a relatively high resistance in the other direction. However, existing semiconductor diodes cause massive losses when used at the high currents needed for superconducting power supplies.

Rectification can alternatively be achieved using switches, for example superconducting switches. However, superconducting switches typically require separate independent power supplies and feedthroughs, which increase complexity and cost. Also the switches may be located within the cryostat, such that heat is dissipated in the cold environment, which adversely affects efficiency.

Diodes formed from superconducting materials are therefore desirable. However, previous designs of superconducting diodes have possessed significant disadvantages. Some have only managed to achieve very small differences in the forward and reverse bias currents, and these are insufficient for the high-power applications mentioned above. Other existing superconducting diodes do not have a high enough critical current to be useful in power applications. Other existing superconducting diodes require advanced manufacturing techniques to manufacture, which is costly and complex.

### 3. OBJECT OF THE INVENTION

It is an object of the technology to provide an improved superconducting diode. Alternatively, it is an object of the technology to provide an improved electrical device for rectifying an alternating current using superconducting materials. Alternatively, it is an object of the technology to at least provide the public with a useful choice.

### 4. SUMMARY OF THE INVENTION

Aspects of the technology relate to electrical devices comprising a length of superconducting material wherein a critical current of the length of superconducting material when current travels through the length of superconducting material in one direction is different to a critical current of the length of superconducting material when current travels through the length of superconducting material in an opposite direction.

In one aspect of the technology there is provided a rectifier comprising a length of superconducting material wherein a critical current of the length of superconducting material when current travels through the length of superconducting material in one direction is different to a critical current of the length of superconducting material when current travels through the length of superconducting material in an opposite direction.

In one aspect of the technology there is provided a superconducting diode. The superconducting diode may comprise a length of superconducting material wherein a critical current of the length of superconducting material when current travels through the length of superconducting material in one direction is different to a critical current of the length of superconducting material when current travels through the length of superconducting material in an opposite direction.

According to one aspect of the technology there is provided an electrical device comprising a length of superconducting material, the length of superconducting material being subject to a plurality of magnetic fields. The effect of the plurality of magnetic fields on the length of superconducting material is different when a current flows through the length of superconducting material in one direction compared to when the current flows through the length of superconducting material in the opposite direction. In some forms, the plurality of magnetic fields comprises: a self-magnetic field generated by the length of superconducting material when current flows through it; and an applied magnetic field generated by a magnetic field generator. In other forms, the plurality of magnetic fields comprises: a first applied magnetic field generated by a first magnetic field generator; and a second applied magnetic field generated by a second magnetic field generator.

According to certain aspects of the technology, there is provided an electrical device comprising a length of superconducting material and a magnetic field generator configured and arranged to apply an applied magnetic field to the length of superconducting material. The length of superconducting material may generate a self-magnetic field when current flows through the length of superconducting material, wherein the self-magnetic field and the applied magnetic field produce a net magnetic field. The magnetic field generator may be configured and arranged such that the net magnetic field has a substantially lower magnitude when a first current flows in the length of superconducting material in the first direction compared to when a second current flows in the length of superconducting material in the second direction. The first and second currents may have equal, or similar, magnitudes. The magnetic field generator may be configured and arranged such that the applied magnetic field is similar to the self-magnetic field when current flows through the length of superconducting material in the first direction.

According to one aspect of the invention there is provided an electrical device. The electrical device may comprise a length of superconducting material. The electrical device may further comprise a magnetic field generator configured and arranged to apply an applied magnetic field to the length of superconducting material such that, when a first current flows in the length of superconducting material in a first direction, the length of superconducting material has a first critical current, and, when a second current flows in the length of superconducting material in a second direction, the second direction being opposite to the first direction, the length of superconducting material has a second critical current, the first critical current being substantially greater than the second critical current.

In examples, the length of superconducting material may generate a self-magnetic field when current flows through the length of superconducting material. The self-magnetic field and the applied magnetic field may produce a net magnetic field. The magnetic field generator may be configured and arranged such that the net magnetic field has a substantially lower magnitude when the first current flows in the length of superconducting material in the first direction compared to when the second current flows in the length of superconducting material in the second direction.

In examples, the magnetic field generator may be configured and arranged such that the applied magnetic field is similar to the self-magnetic field when current flows through the length of superconducting material in the first direction.

In examples, the length of superconducting material may be a first length of superconducting material and the magnetic field generator may comprise a second length of superconducting material positioned proximate the first length of superconducting material. The applied magnetic field may be generated when a current flows through the second length of superconducting material.

In examples, when a direction in which current flows through the second length of superconducting material is changed to an opposite direction, the first and second directions of current flow through the first length of superconducting material may be swapped.

In examples, the magnetic field generator may comprise a permanent magnet positioned proximate the length of superconducting material.

In examples, the magnetic field generator may comprise two permanent magnets positioned on the same side of the length of superconducting material. The polar axes of the two permanent magnets may be arranged substantially anti-parallel to each other. The polar axes of the two permanent magnets may be oriented substantially perpendicular to a face of the length of superconducting material facing towards the magnets.

According to one aspect of the invention there is provided an electrical device. The electrical device may comprise a length of superconducting material comprising two substantially parallel opposed faces. The electrical device may further comprise a magnetic field generator comprising two permanent magnets positioned on the same side of the length of superconducting material. Polar axes of the two permanent magnets may be arranged substantially anti-parallel to each other. The polar axes of the two permanent magnets may be oriented substantially perpendicular to the faces of the length of superconducting material. The magnetic field generator may be configured and arranged to apply an applied magnetic field to the length of superconducting material such that, when a first current flows in the length of superconducting material in a first direction, the length of superconducting material has a first critical current, and, when a second current flows in the length of superconducting material in a second direction, the second direction being opposite to the first direction, the length of superconducting material has a second critical current, the first critical current being substantially greater than the second critical current.

In examples, the length of superconducting material may generate a self-magnetic field when current flows through the length of superconducting material. The self-magnetic field and the applied magnetic field may produce a net magnetic field. The magnetic field generator may be configured and arranged such that the net magnetic field has a substantially lower magnitude when the first current flows in the length of superconducting material in the first direction compared to when the second current flows in the length of superconducting material in the second direction.

In examples, the magnetic field generator may be configured and arranged such that the applied magnetic field is similar to the self-magnetic field when current flows through the length of superconducting material in the first direction.

In examples, the two permanent magnets may be positioned equidistant from the length of superconducting material.

In examples, the length of superconducting material may comprise a length, a width and a depth. The depth may be the distance between the two substantially parallel opposed faces. The length may be significantly larger than the width. The width may be significantly larger than the depth.

In examples, the two permanent magnets may be positioned in substantial alignment along the length of the length of superconducting material.

In examples, both permanent magnets may be displaced from the length of superconducting material by substantially the same distance in a direction perpendicular to the faces of the length of superconducting material.

In examples, the two permanent magnets may be separated by a spacing in a direction parallel to the width of the length of superconducting material. The spacing may be greater than the width of the length of superconducting material.

In examples, the magnetic field generator may comprise third and fourth permanent magnets positioned on the opposite side of the length of superconducting material from the two permanent magnets.

According to one aspect of the invention there is provided an electrical device. The electrical device may comprise a length of superconducting material. The electrical device may further comprise a first magnetic field generator configured and arranged to apply a first applied magnetic field to the length of superconducting material. The electrical device may comprise a second magnetic field generator configured and arranged to apply a second applied magnetic field to the length of superconducting material. The first applied magnetic field and the second applied magnetic field may produce a net magnetic field. The first and second magnetic field generators may be configured and arranged such that, when a first current flows in the length of superconducting material in a first direction, the net magnetic field has a first magnitude and the length of superconducting material has a first critical current, and, when a second current flows in the length of superconducting material in a second direction, the second direction being opposite to the first direction, the net magnetic field has a second magnitude and the length of superconducting material has a second critical current. The first magnitude may be substantially lower than the second magnitude, and the first critical current may be substantially greater than the second critical current.

In examples, the magnetic field generator may comprise a magnetic core formed from a material having a high magnetic permeability. The magnetic core may be positioned to channel the applied magnetic field towards the length of superconducting material.

In examples, the magnetic core may comprise a gap and the length of superconducting material may be positioned in the gap.

In examples, the magnetic field generator may be a first magnetic field generator and the applied magnetic field may be a first applied magnetic field. The electrical device may further comprise a second magnetic field generator configured and arranged to apply a second applied magnetic field to the length of superconducting material. The first applied magnetic field and the second applied magnetic field may produce a net magnetic field. The first and second magnetic field generators may be configured and arranged such that the net magnetic field has a substantially lower magnitude when the first current flows in the length of superconducting material in the first direction compared to when the second current flows in the length of superconducting material in the second direction.

In examples, the length of superconducting material may be a first length of superconducting material and the electrical device further may comprise a second length of superconducting material, the second length of superconducting material being joined in series to the first length of superconducting material. The second magnetic field generator may comprise the second length of superconducting material such that the second applied magnetic field is produced by the second length of superconducting material.

In examples, the second length of superconducting material may be arranged in a coil. The first length of superconducting material may be positioned inside the coil.

In examples, a cross-sectional area of the first length of superconducting material may be less than a cross-sectional area of the second length of superconducting material.

In one aspect of the technology there is provided a rectifier comprising an electrical device according to any one or more of the other aspects of the technology.

Further aspects of the technology, which should be considered in all its novel aspects, will become apparent to those skilled in the art upon reading of the following description which provides at least one example of a practical application of the technology.

### 5. BRIEF DESCRIPTION OF THE DRAWINGS

One or more embodiments of the technology will be described below by way of example only, and without intending to be limiting, with reference to the following drawings, in which:

FIG. 1 shows an exemplary electric-field versus current graph for a high-temperature superconductor;

FIG. 2 is an illustration of graphs of electric field against current for a superconducting material when three external magnetic fields of different magnitude are applied;

FIG. 3 is a schematic illustrated of an electrical device according to one form of the technology;

FIG. 4A is a graph showing the variation of the strength of the magnetic fields on the length of superconducting material of FIG. 3 when current flows through the length of superconducting material in one direction;

FIG. 4B is a graph showing the variation of the strength of the magnetic fields on the length of superconducting material of FIG. 3 when current flows through the length of superconducting material in the opposite direction;

FIG. 5 is a schematic illustration of an electrical device according to one form of the technology similar to the arrangement of FIG. 3;

FIG. 6 is a graph showing experimental results of the forward and reverse critical currents and the diodicity of the diode arrangement of FIG. 5;

FIG. 7 is a graph showing experimental results of current through an electrical device according to another form of the technology;

FIG. 8 shows a schematic for a modelling geometry for an electrical device according to one form of the technology;

FIG. 9 is a diagram showing the results of measuring diodicity using the simulation of FIG. 8;

FIG. 10A is a field line plot for an exemplary arrangement of an electrical device according to one form of the technology;

FIG. 10B is a field line plot for another exemplary arrangement of an electrical device according to one form of the technology;

FIG. 11 is a perspective view illustration of an electrical device according to another form of the technology;

FIG. 12 is an end cross-sectional view illustration of the electrical device of FIG. 11;

FIG. 13 is a schematic view illustration of an electrical device according to another form of the technology;

FIG. 14A is a schematic illustration of an electrical device according to one form of the technology;

FIG. 14B is a circuit diagram illustrating the electrical device shown in FIG. 14A;

FIG. 15A is a graph showing the variation of the strength of the magnetic fields on the length of superconducting material of FIGS. 14A and 14B when current flows through the length of superconducting material in one direction;

FIG. 15B is a graph showing the variation of the strength of the magnetic fields on the length of superconducting material of FIGS. 14A and 14B when current flows through the length of superconducting material in the opposite direction;

FIG. 16 is a graph showing current against electric field for a length of superconducting material according to computer modelling of the form of the technology shown in FIG. 14A; and

FIG. 17 is a graph showing the relationship between certain parameters in an electrical device according to the form of the technology shown in FIG. 14A.

### 6. DETAILED DESCRIPTION OF PREFERRED EMBODIMENTS OF THE INVENTION

### 6.1. Superconductivity

A superconductor is a material that exhibits zero electrical resistance below a certain temperature known as the critical temperature, T_{c}. This lack of resistance is the result of a phenomenon known as the Meissner Effect, which is the complete expulsion of any magnetic field from the superconductor. Superconductors are perfect diamagnetic materials up until a certain magnetic field strength known as the critical field, B_{c}. At this point the superconductor cannot keep the magnetic field out, and thus the superconducting phenomena is destroyed. This critical field also implies that there is a limit to the current that the superconductor can carry, known as the critical current, I_{c}.

There are two types of superconductors, named type I and type II. Type I superconductors are typically pure metals and behave as described above. Type II superconductors behave differently. Type II superconductors allow some magnetic field to penetrate at a critical field H_{c2}<H_{c} without transitioning out of the superconducting state. Because of this, type II superconductors can carry much more current than type I superconductors, making them useful for practical applications.

The critical temperature for a superconductor is conventionally defined as the temperature below which the resistivity of the superconductor drops to zero or near zero. In other words, a superconductor is said to be in its superconducting state when the temperature of the superconductor is below the critical temperature and in a non-superconducting state when the temperature is above the critical temperature. Many superconductors have a critical temperature which is near absolute zero; for example, mercury is known to have a critical temperature of 4.1K. It is however also known that some materials can have critical temperatures which are much higher such as 30K to 125K; for example, magnesium diboride has a critical temperature of approximately 39K, while yttrium barium copper oxide (YBCO) has a critical temperature of approximately 92K. These superconductors are often generally referred to as high-temperature superconductors (HTSs).

### 6.1.1. Critical Current

The critical current for a high-temperature superconductor wire or tape is conventionally defined as the current flowing in a superconductor wire/tape which results in an electric field drop along the wire of 100 μV/m (=1 μV/cm). The critical current is a function of both the superconducting material used, and the physical arrangement of the superconducting material. For example, a wider tape/wire may have a higher critical current than a thinner tape/wire constructed of the same material. Nevertheless, throughout the specification, reference to the critical current of the superconductor/superconducting material is made to simplify the discussion.

In a superconductor/superconducting material, if the current I is approximately equal to the critical current I_{c}, the resistance of the superconductor is non-zero, but small. However, if I is much larger than the critical current I_{c}, the resistance of the superconductor becomes sufficiently large to cause heat dissipation which can heat the superconductor to a temperature above its critical temperature, which in turn causes it to no longer be superconducting. This condition is sometimes referred to as a “quench” and can be damaging to the superconductor itself.

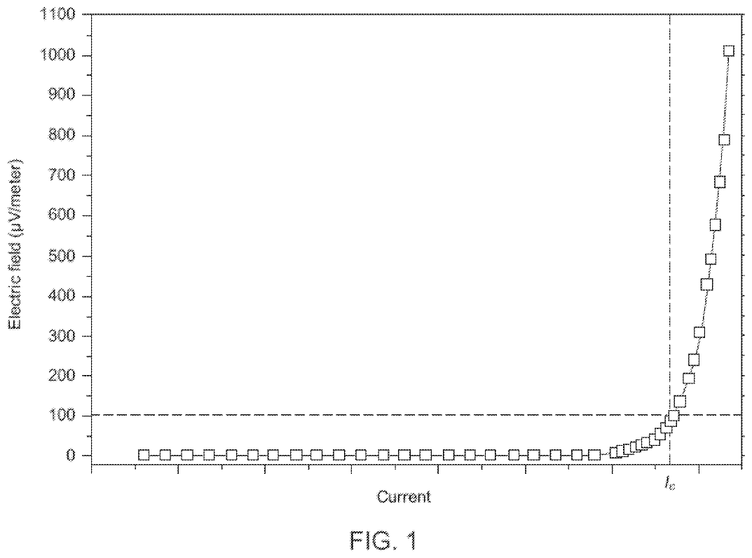

FIG. 1 shows an exemplary plot depicting the internal electric-field versus current curve for a high-temperature superconductor. The electric-field shown in this plot is related to resistance via the following equation:

$$E = \frac{IR}{L}$$

where:
E is the electric field;
I is the current through the superconductor;
R is the resistance of the wire; and
L is the length of the wire.

Accordingly, the plot of FIG. 1 is related to the resistance per-unit length for the superconductor and, because the curve depicted is non-linear, the resulting resistance for the superconductor is non-linear with current.

In FIG. 1 it can be seen that the electric field strength in the superconductor is substantially zero below the critical current I_{c} for the superconductor. As the current in the superconductor approaches the critical current, the electric-field in the superconductor starts to increase. At the critical current, the electric-field in the superconductor is 100 μV/m. Further increasing the current in the superconductor above the critical current results in rapid increases in the electric-field strength in the conductor.

The transition from the superconducting to the normal state in HTS materials, such as is shown in FIG. 1, can be described by an empirical law known as the E-J power law:

$$E = {{E}_{0} ( \frac{J}{{J}_{c}} )}^{n}$$

where E is the electric field in the conductor, J is the current density, and n is an experimentally defined unitless parameter which governs the steepness of the transition. In most superconductors, n has a value between 25-30. The critical current density J_{c} is defined by some arbitrarily chosen threshold field E₀, which may be 100 μV/m (=1 μV/cm) as explained above.

In this specification reference may be made to the relative resistances of a superconducting material and components comprising a superconducting material. More particularly, the specification refers to a superconducting material being in a low-resistance or higher-resistance state. It will be appreciated that, when in a superconducting state, superconducting materials can have a resistance which is zero or substantially zero, and as such these resistances are often expressed in terms of the electric field present across the superconducting material for a given current. Nevertheless, throughout the present specification, reference is made to relative resistances, for example low-resistance and higher-resistance states of the superconducting material, in order to simplify the discussion.

The term ‘low-resistance state’ may refer to when the superconducting material has a resistance that is close to or substantially zero in the superconducting state, or when the material has a low resistance in a partially superconducting state. The term ‘higher-resistance’ state refers to a state in which the superconducting material has a resistance that is substantially greater than the resistance in the low resistance state, for example a substantially non-zero resistance or a resistance that is close to zero but substantially greater than the resistance in the low-resistance state. For the avoidance of doubt, a higher-resistance state as referred to in this specification may, unless the context clearly indicates otherwise, include a superconducting state.

Similarly, where in this specification reference is made to a superconductor being in a higher-resistance state as a result of a current carried by the superconductor exceeding the critical current, it should be understood that, unless the context clearly indicates otherwise, the higher-resistance state may also be achieved if the current carried by the superconductor approaches or is substantially equal to the critical current.

In describing the technology in this specification, material and components comprising the material are referred to as “superconducting”. This term is commonly used in the art for such materials and should not be taken to mean that the relevant material is always in a superconducting state. Under certain conditions the material and components comprising the material may not be in a superconducting state. That is, the material may be described as being superconductive but not superconducting.

### 6.1.2. Superconducting Materials

Certain forms of the present technology may comprise a variety of types of superconducting material. For example, forms of the technology may comprise high-temperature superconducting (HTS) materials. Exemplary HTS materials suitable for use in the forms of technology described include copper-oxide superconductors, for example a rare-earth barium copper oxide (ReBCO) such as yttrium barium copper oxide, gadolinium barium copper oxide or bismuth strontium calcium copper oxide (BSCCO) superconductors, and iron-based superconductors. BSCCO superconductors typically have a strong interdependence between critical current and an applied magnetic field, which may make them particularly suitable for some forms of the present technology. Other types of superconductors may be used in other forms of the technology.

While forms of the technology will be described in relation to high-temperature superconductors, it should be understood that other forms of the technology may use other types of superconductor, for example low-temperature superconductors, in their place.

### 6.1.3. Effect of Magnetic Field on Superconductors

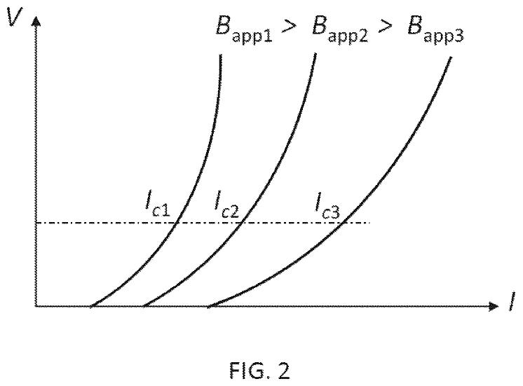

The critical current in a superconductor is dependent on the external magnetic field applied to the superconductor. More particularly, the critical current decreases as a higher external magnetic field is applied to the superconductor, up to the value of the critical field, above which the superconductor is no longer in the superconducting (low resistance) state. This relationship is shown in FIG. 2, which is an illustration of graphs of electric field against current for a superconducting material when three external magnetic fields of different magnitude are applied. The highest magnitude of external magnetic field, Bₐₚₚ₁, results in the lowest critical current, I_{c1}. In some forms, the external magnetic field to achieve this effect may be applied perpendicular to the length of superconductor in which the critical current is reduced, or suppressed. The applied magnetic field may be in one direction only, which may be referred to as a DC field, as compared to a time-varying magnetic field whose direction cycles, for example sinusoidally, which may be referred to as an AC field.

For all superconductors, the critical current drops off sharply with only a small applied magnetic field. This means that a small change in the applied magnetic field can result in a large change in the critical current. This relationship is dependent on the superconducting material and the way the length of superconducting material that carries current was manufactured.

It should be appreciated that this mechanism to reduce or suppress the critical current by applying an external magnetic field, e.g. a DC field, is different from the phenomenon of dynamic resistance. This occurs when a superconductor is exposed to a time-varying magnetic field while carrying a DC transport current. This creates a DC electrical resistance in the superconductor, which may be sufficiently large that the superconductor switches into a higher-resistance state.

### 6.2. Superconducting Diode

### 6.2.1. Principle of Operation

Forms of the technology described in this specification are electrical devices that may be referred to as “superconducting diodes”. The term “diode” is used in this specification to refer to an electrical device that exhibits different resistive properties (or, equivalently, conductance) when current flows through the device in one direction compared to when current flows through the device in the opposite direction. In the case of a conventional semiconductor diode, the resistance of the diode is low (ideally zero) when the current flows in one direction and high (ideally infinite) when the current flows in the opposite direction. Forms of the technology described in this specification are electrical devices comprising a length of superconducting material in which a critical current of the length of superconducting material when current travels through the length of superconducting material in one direction is different to a critical current of the length of superconducting material when current travels through the length of superconducting material in an opposite direction. The term “diode” is applied to such electrical devices because of this change in the resistive property of the device based on the direction of the current flowing through the device. In the forward bias direction of such diodes, a relatively large current can pass while the diode is in a lower resistance (e.g. superconducting) state, so no resistance is experienced. In the reverse bias direction, the diode may be configured such that the same magnitude of current flowing in the opposite direction experiences, or would experience, a higher level of resistance (e.g. because the current approaches, is similar to or exceeds the critical current). A lower magnitude current may experience the lower resistance state of the diode in the reverse bias direction. The superconducting diodes described in this specification may be considered to be the electromagnetic dual of a semiconductor diode.

The general principle of operation of electrical devices according to certain forms of the technology, that may be described as superconducting diodes, is that the length of superconducting material that exhibits the diode effect is subject to a plurality of magnetic fields (for example, two magnetic fields) and there is a difference in the effect of the magnetic fields in combination when current flows through the length of superconducting material in one direction compared to when current (for example, of the same or similar magnitude) flows through the length of superconducting material in the other, opposite direction. The plurality of magnetic fields in combination may be referred to as the net magnetic field. The asymmetry results in the length of superconducting material having a different critical current depending on the direction in which current flows through the length of superconducting material, creating the diode effect.

In some forms of the technology, the plurality of magnetic fields comprise a self-magnetic field generated by the length of superconducting material when current flows through it, and an applied magnetic field generated by a magnetic field generator. In other forms, the plurality of magnetic fields comprises a first applied magnetic field generated by a first magnetic field generator, and a second applied magnetic field generated by a second magnetic field generator. In some of these latter forms, the self-magnetic field from the length of superconducting material may be negligible compared to the applied magnetic fields.

In some forms of the technology, the self-magnetic field contributes to the net magnetic field, and the strength of the self-magnetic field depends on the magnitude of the current flowing through the length of superconducting material. In addition, the critical current of the length of superconducting material depends on the net magnetic field applied to the length of superconducting material. Forms of the technology relate to electrical devices in which a length of superconducting material has a first critical current when a first current of a certain magnitude flows through the length of superconducting material in one direction, and the length of superconducting material has a second critical current when a second current flows through the length of superconducting material in an opposite direction to the first current. This difference in critical currents for currents flowing through the length of superconducting material with equal magnitude but opposite directions is the asymmetry that creates the diode effect in certain forms of the technology.

In operation, currents flowing through the forms of superconductor diode described in this specification may be substantially lower than, approaching or substantially equal to, and/or substantially greater than the critical current of the length of superconducting material that exhibits the diode effect. It will be apparent that, in the forward bias configuration of the superconductor diode, in which the critical current is relatively high, the diode may carry currents substantially less than the critical current such that the length of superconducting material is in the superconducting state. In the reverse bias configuration, in which the critical current is relatively low, the diode may carry currents that are substantially lower than, approaching or substantially equal to, and/or substantially greater than the critical current of the length of superconducting material. In some forms, in the reverse bias configuration, the magnitude of the current may be such that the length of superconducting material may remain in the superconducting state but may have a resistance that is substantially greater than the resistance of the length of superconducting material in the forward bias configuration with a current of similar magnitude. Suitable magnitudes of current that enables the diode to operate in the desired states, for a given form of diode, may be readily determined through experimentation.

It will be appreciated that, in certain forms, an alternating current (AC) is provided to the diode, for example where the diode is used as, or comprised as part of, a rectifier.

### 6.2.2. Diodicity

Electrical devices that operate in the described way, and may be referred to as superconducting diodes, may possess a property that will be referred to as “diodicity”. The diodicity is a measure of the diode effect produced by the electrical device, i.e. the extent to which the critical current of the length of superconducting material differs when current flows in one direction compared to the other direction.

In certain forms, the diodicity D may be defined as:

$$D = \frac{{I}_{c , forward} - {I}_{c , reverse}}{{I}_{c , forward}}$$

where I_{c,forward} is the critical current of the length of superconducting material when the current flows in one direction (which may be referred to as the forward bias direction) and I_{c,reverse} is the critical current of the length of superconducting material when the current flows in the opposite direction (which may be referred to as the reverse bias direction). The diodicity of any device satisfies: 0≤D≤1. A superconducting diode device having a diodicity of 0 has critical currents that are equal in both forward and reverse bias directions, while a superconducting diode device having a diodicity of 1 has a critical current of zero in the reverse bias direction and will allow current to flow in only one direction.

### 6.2.3. Length of Superconducting Material

Certain forms of the technology relate to electrical devices 100 comprising a length of superconducting material 200. The length of superconducting material 200 is the portion of superconductor in which the diode effect is produced. The length of superconducting material 200 may be formed from any superconducting material, including any of the examples mentioned earlier. In certain forms of the technology, the length of superconducting material 200 may be formed from a HTS material. In certain forms, the length of superconducting material 200 in which the diode effect is produced is a single strand of superconducting material, for example there may be no loops or branches present in the length of superconducting material 200.

### 6.2.3.1. Superconducting Tape

In certain forms of the technology, the length of superconducting material 200 may take the form of a tape, i.e. a length of material having a length that is significantly larger than its width and its depth, and a width that is significantly larger than its depth. The tape may have two substantially parallel opposed faces, where the faces are separated by the depth of the tape.

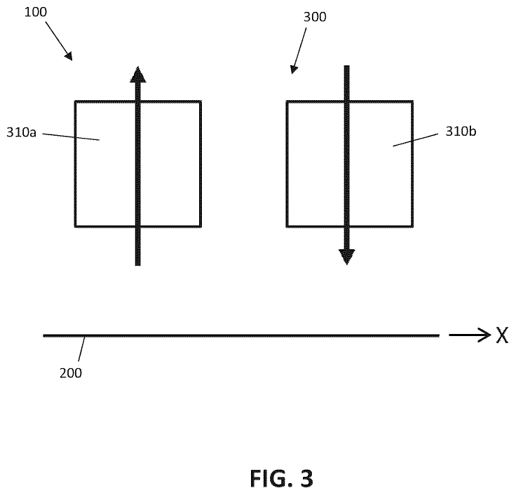

An example of an electrical device 100 comprising a length of superconducting material 200 in the form of a tape is illustrated in FIG. 3. FIG. 3 is a view end-on to the tape, meaning that the length of the tape extends in and out of the page. When electrical current is passed through the tape, the current flows along the length of the tape, i.e. in or out of the page depending on the direction of current flow. The width of the tape extends across the page in FIG. 3 in the direction of arrow X. Unless stated otherwise, in this specification, the following co-ordinate convention will be used when describing directions in relation to a length of superconducting material 200 in the form of a tape: the x-direction is across the width of the tape (i.e. left-right across the page in FIG. 3); the y-direction is perpendicular to the opposed faces of the tape (i.e. up-down on the page in FIG. 3); and the z-direction is along the length of the tape (i.e. in-out of the page in FIG. 3).

In other forms of the technology, the length of superconducting material 200 may take another form, for example a wire, including a wire of substantially circular cross-sectional shape, or lengths of superconducting material having other cross-sectional shapes.

### 6.2.3.2. Self-Magnetic Field of Length of Superconducting Material

A moving electric charge generates a magnetic field. Consequently, when current flows through the length of superconducting material 200, a magnetic field is produced. In this specification, the magnetic field produced when current flows through the length of superconducting material 200 is referred to as the self-magnetic field. The field lines of the self-magnetic field are around the length of superconducting material 200 in a direction in accordance with the ‘right-hand grip rule’. In some forms of the technology, the self-magnetic field interacts with another magnetic field applied to the length of superconducting material 200 in order to create the diode effect, as will be described.

### 6.2.4. Cryostat

Even if not expressly stated in relation to specific forms, forms of the technology comprise electrical devices 100 which comprise a cryostat to house the length of superconducting material 200 and to maintain a temperature suitable for the superconducting material to adopt the superconducting state. Any suitable form of cryostat or cooling mechanism may be used.

### 6.2.5. Magnetic Field Generator

Forms of the technology are related to an electrical device that comprises a magnetic field generator 300. While specific examples of magnetic field generators will be described, the term may refer to any component or assembly that generates a magnetic field. Examples of magnetic field generators include magnets (for example permanent magnets and electromagnets) and conductors carrying currents (for example a length of superconducting material carrying a current).

In certain forms, the magnetic field generator may 300 comprise a magnetic core 340 formed from a material having a high magnetic permeability, for example iron or ferrite. The magnetic core 340 may be positioned relative to a magnet in order to channel the applied magnetic field generated by the magnetic field generator 300 towards the length of superconducting material 200. For example, a permanent magnet may be positioned in close proximity to the magnetic core 340, for example sandwiched between two portions of the magnetic core 340. In another form, an electromagnet may be formed by winding a conductor around a portion of the magnetic core 340 and passing current through the conductor in order to generate a magnetic field through the magnetic core 340. In certain forms, the magnetic core 340 may comprise a gap 350, and the length of superconducting material 200 may be positioned in the gap 350.

The magnetic core 340 may comprise any suitable shape or form to concentrate the lines of magnetic flux onto the length of superconducting material 200. For example, the magnetic core 340 may comprise one or more tapered ends adjacent to the length of superconducting material 200. In other forms, the magnetic core 340 may comprise a plurality of teeth adjacent to the length of superconducting material 200.

### 6.2.6. Types of Superconducting Diode

In the following description, different types of electrical devices that may be considered superconducting diodes will be described. In one type of such a device, a different net magnetic field may be produced when the current flows through the length of superconducting material 200 in one direction compared to when current flows through the length of superconducting material 200 in the opposite direction because of a different net effect of the self-magnetic field generated by the length of superconducting material 200 and an applied magnetic field generated by a magnetic field generator 300. In another type, the different net magnetic field produced when the current flows in different directions may result from a difference in the net magnetic field produced by two (or more) magnetic field generators.

Furthermore, another categorisation of forms of the technology described in this specification may be active and passive devices. Forms of the technology that may be described as passive devices require no additional electric power source to create the diode effect other than the current flowing through the length of superconducting material 200 in which the diode effect is produced. In forms of the technology that may be described as active devices, an additional electric power source is used to create the diode effect.

These different types of devices will be described in further detail in relation to exemplary forms of the technology. Any one or more of the exemplary electrical devices described may be incorporated, in some forms of the technology, into a rectifier for rectifying an alternating current.

### 6.2.6.1. Self-Magnetic Field and Applied Magnetic Field

In certain forms of the technology, a different net magnetic field on the length of superconducting material 200 may be produced when current flows through the length of superconducting material 200 in one direction compared to when current flows through the length of superconducting material 200 in the opposite direction because of a different net effect of the self-magnetic field generated by the length of superconducting material 200 and the applied magnetic field generated by a magnetic field generator 300. For example, the magnetic field generator 300 may be configured and arranged such that the net magnetic field has a substantially lower magnitude when current flows in the length of superconducting material in one direction compared to when current (for example current of the same magnitude) flows in the length of superconducting material in the opposite direction. In some forms, this may be achieved by the magnetic field generator being configured and arranged such that the applied magnetic field is similar to the self-magnetic field when current flows through the length of superconducting material in the first direction. This similarity in the fields creates an additive effect on the net magnetic field on the length of superconducting material 200. When current flows through the length of superconducting material in the opposite direction, the fields are now similar but opposite, creating a cancelling effect and the net magnetic field on the length of superconducting material 200 is consequently relatively low. Since the critical current of the length of superconducting material 200 depends on the magnetic field it is subject to, with the critical current being lower when a higher field is applied, the critical current of the length of superconducting material 200 is higher when the self-magnetic field of the length of superconducting material 200 and the applied magnetic field at least partially cancel each other.

It certain forms, the applied magnetic field may be similar to the self-magnetic field of the length of superconducting material 200 in how at least one of its magnitude or direction varies in the region proximate the length of superconducting material 200. In certain forms the applied magnetic field may be similar to the self-magnetic field of the length of superconducting material 200 in how both the magnitude and direction vary in the region proximate the length of superconducting material 200. In certain forms, the applied magnetic field may be similar to the self-magnetic field of the length of superconducting material 200 in terms of the magnitude of the component of the magnetic field in a direction perpendicular to the surface of the length of superconducting material 200 (e.g. the y-direction of FIG. 3) at or proximate the surface of the length of superconducting material 200, and the variation of that magnitude along the width of the length of superconducting material 200 (i.e. in the x-direction of FIG. 3). In certain forms, it may be considered that the applied magnetic field is sufficiently similar to the self-magnetic field if a desired level of diodicity is obtained. In certain forms, the more similar the applied magnetic field is to the self-magnetic field, in magnitude and/or direction in the region proximate the length of superconducting material 200, the higher the level of diodicity may be.

### 6.2.6.1.1. Permanent Magnets

In some forms of the technology, the electrical device 100 comprises a magnetic field generator 300 comprising one or more magnets to generate the applied magnetic field. Several such exemplary forms are illustrated in FIGS. 3, 8, 10A and 10B. In these examples, electrical device 100 comprises a length of superconducting material 200 and two permanent magnets 310a and 310b positioned proximate the length of superconducting material 200. The proximity of the permanent magnets 310a and 310b to the length of superconducting material 200 may depend on the selection of permanent magnets, for example the strength of the magnets, however the proximity may be such that the effects described in the following description may be achieved. In certain forms, the proximity may be such that the field strength of the magnetic field applied by the permanent magnets on the length of superconducting material 200 is similar to, for example of a similar order of magnitude to, the field strength of the self-magnetic field produced by the length of superconducting material 200 when typical magnitudes of operating current pass through the length of superconducting material 200.

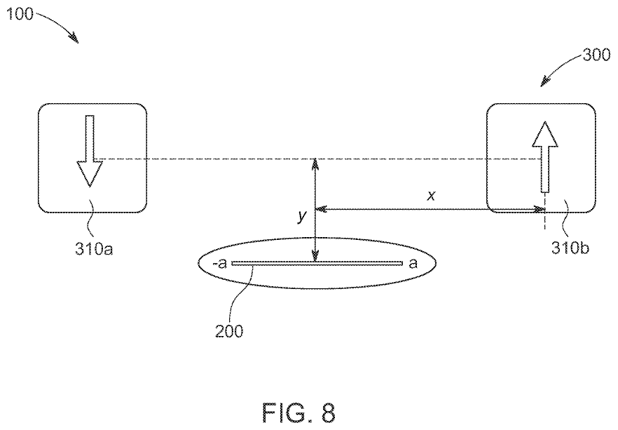

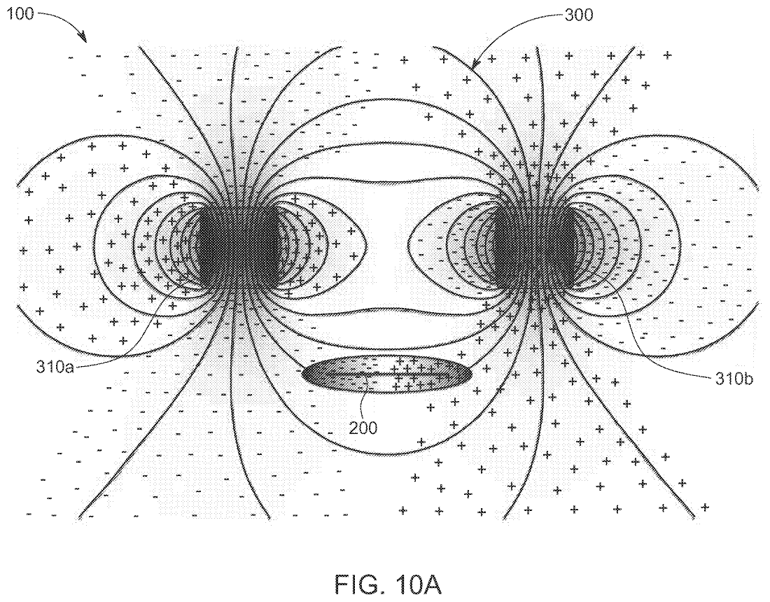

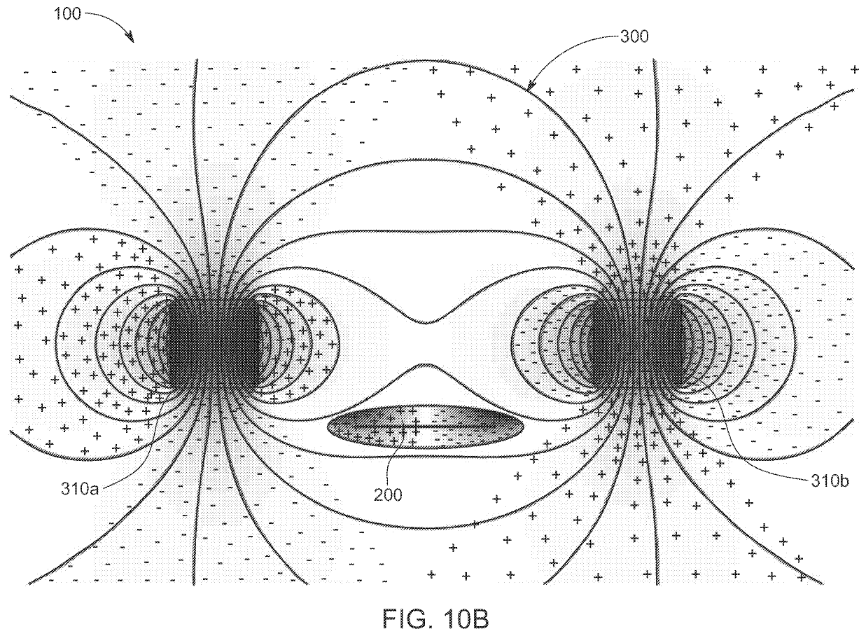

The permanent magnets are arranged to produce an applied magnetic field having a shape and/or strength that is similar to the self-magnetic field produced by the length of superconducting material 200 when current flows through it. Exemplary arrangements of two permanent magnets 310a and 310b are illustrated in FIGS. 3, 8, 10A and 10B. In these forms, both permanent magnets 310a and 310b are placed on the same side of the length of superconducting material 200. The permanent magnets 310a and 310b are positioned equidistant from the length of superconducting material 200. The permanent magnets 310a and 310b are displaced from the length of superconducting material 200 in the y-direction (i.e. perpendicular to the face of the tape). Both magnets may be displaced in this direction by substantially the same distance. The permanent magnets 310a and 310b in these forms are oriented so that the polar axes of the magnets are substantially anti-parallel (i.e. in opposite directions to each other). Furthermore, the polar axes of the magnets may be arranged substantially perpendicular to the face of the tape forming the length of superconducting material 200, i.e. the polar axes are oriented substantially parallel to the y-direction. In the forms of FIGS. 8, 10A and 10B the spacing between the permanent magnets 310a and 310b in the x-direction (i.e. in the direction of the width of the length of superconducting material 200) is greater than the width of the length of superconducting material 200.

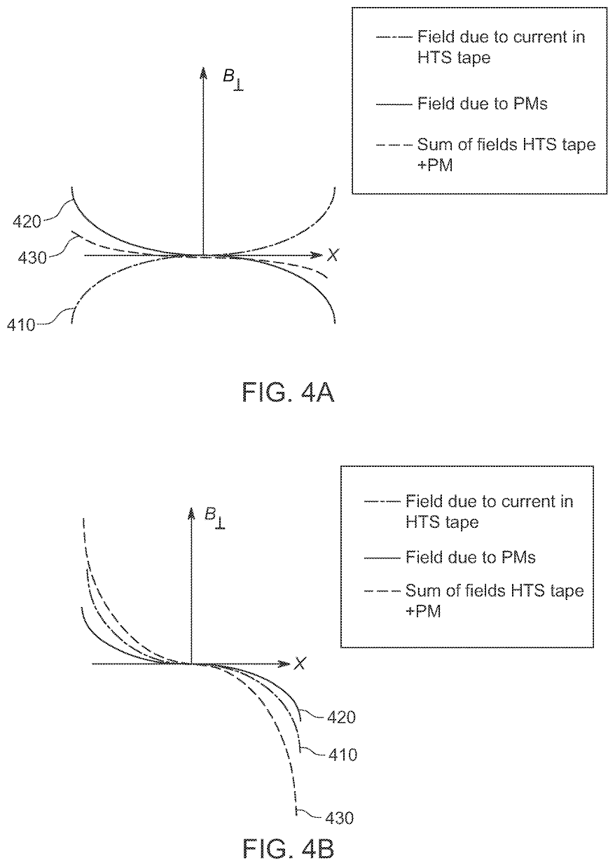

This arrangement of permanent magnets 310a and 310b is useful in producing an applied magnetic field having a similar magnetic field strength profile across the width of the length of superconducting material 200 as the self-magnetic field of the length of superconducting material 200. FIGS. 4A and 4B are graphs showing the variation of the strength of the magnetic fields on the length of superconducting material 200 of FIG. 3. The magnetic field strength indicated by the vertical axis is the magnetic field strength perpendicular to the face of the length of superconducting material 200 in FIG. 3, i.e. in the y-direction. The horizontal axis in FIGS. 4A and 4B is distance along the width of the length of superconducting material 200, i.e. in the x-direction. In each graph, the line 410 illustrates the profile of the self-magnetic field generated by the length of superconducting material 200 when current flows through it. The line 420 illustrates the profile of the applied magnetic field generated by the permanent magnets 310a and 310b. The line 430 is the net magnetic field produced by the combination of the self-magnetic field generated by the length of superconducting material 200 and the applied magnetic field of the permanent magnets 310a and 310b, i.e. the sum of the lines 410 and 420. It can be seen from FIG. 4B that, when current flows through the length of superconducting material 200 in one direction, the self-magnetic field has a similar profile to the applied magnetic field, i.e. lines 410 and 420 are similar in shape.

The state of the magnetic fields illustrated in FIG. 4A is the ‘forward bias’ state of the electrical device 100. In this state, a current is flowing through the length of superconducting material 200 in one direction such that the self-magnetic field produced by the length of superconducting material 200 is similar in strength but opposite in direction to the applied magnetic field of the permanent magnets 310a and 310b at each point along the width of the length of superconducting material 200. Consequently, the magnetic fields at least partially cancel each other out, or negatively interfere, and the net magnetic field (as illustrated by line 430) is relatively low across the whole width of the length of superconducting material 200. The relatively low net magnetic field strength means that there is relatively little suppression of the critical current of the length of superconducting material 200. For example, the suppression of the critical current of the length of superconducting material 200 is less than occurs when the length of superconducting material 200 is subject to only the applied magnetic field of the permanent magnets 310a and 310b, i.e. when there is no current flowing through the length of superconducting material 200. Consequently, the critical current of the length of superconducting material 200 in the forward bias state, I_{c,forward}, is greater than the critical current of the length of superconducting material 200 when there is no current flowing, I_{c,0}, i.e. |I_{c,forward}|>|I_{c,0}|.

The state of the magnetic fields illustrated in FIG. 4B is the ‘reverse bias’ state of the electrical device 100. In this state, a current is flowing through the length of superconducting material 200 in the opposite direction to the direction that the current is flowing in the forward bias state. Therefore, the self-magnetic field produced by the length of superconducting material 200 is in the same direction as, and may be similar in strength to, the applied magnetic field of the permanent magnets 310a and 310b at each point along the width of the length of superconducting material 200. Consequently, the magnetic fields positively interfere and the net magnetic field (as illustrated by line 430) is relatively high in certain regions across the width of the length of superconducting material 200. The relatively high net magnetic field strength in these regions (compared to the forward bias state) means that there is relatively high suppression of the critical current of the length of superconducting material 200 in these regions. For example, the suppression of the critical current of the length of superconducting material 200 is greater than occurs when the length of superconducting material 200 is subject to only the applied magnetic field of the permanent magnets 310a and 310b, i.e. when there is no current flowing through the length of superconducting material 200. Consequently, the critical current of the length of superconducting material 200 in the reverse bias state, I_{c,reverse}, is less than the critical current of the length of superconducting material 200 when there is no current flowing, I_{c,0}, i.e. |I_{c,forward}|>|I_{c,0}|. Consequently, |I_{c,reverse}|<|I_{c,forward}|. This creates a diodicity and a diode effect in the length of superconducting material 200.

In the form of technology illustrated in FIG. 3, the diode effect is mainly achieved in edge regions of the length of superconducting material 200. This is shown by the relative large change in the net magnetic field in regions of large absolute values of x in the forward bias configuration of FIG. 4A compared to the reverse bias configuration of FIG. 4B. For x=0 and for low values of x, corresponding to the middle region of the length of superconducting material 200, the net magnetic field strength is similarly low in both the forward and reverse bias configurations. Consequently the diodicity of the edge regions of the length of superconducting material 200 is greater than that of the middle region of the length of superconducting material 200.

In other forms of the technology, the electrical device 100 may comprise a magnetic field generator 300 comprising a different number of magnets and/or other arrangements of magnets. For example, in one alternative form, the magnetic field generator 300 comprises a single permanent magnet 310 positioned on one side of the length of superconducting material 200 (i.e. spaced apart from the length of superconducting material 200 in the y-direction and opposite a face of the length of superconducting material 200) with the polar axis of the magnet 310 substantially parallel to the width of the length of superconducting material 200, i.e. with the polar axis substantially parallel to the x-direction.

In other forms, the magnetic field generator 300 may comprise three, four or more permanent magnets arranged on one side of the length of superconducting material 200, similar to the arrangement of FIG. 3 but with more magnets. The magnets may be arranged with polar axes of alternating magnets anti-parallel to each other. The magnets may be arranged in an array, for example in a line or other arrangement.

In yet other forms, the magnetic field generator 300 may comprise one or more magnets on one side of the length of superconducting material 200 (i.e. positioned with a positive y-direction co-ordinate) and one or more magnets on the other side of the length of superconducting material 200 (i.e. positioned with a negative y-direction co-ordinate). For example, in one form, the magnetic field generator 300 comprises two permanent magnets 310a and 310b arranged in the manner shown in FIG. 3 (and described above) and an additional two permanent magnets positioned on the other side of the length of superconducting material 200 (i.e. below the length of superconducting material 200 as shown in FIG. 3). The two additional permanent magnets may also be arranged with their polar axes substantially anti-parallel to each other and substantially parallel to the y-direction.

Forms of the technology in which the applied magnetic field is generated by permanent magnets may be considered to be passive electrical devices since the electrical device 100 comprises no additional electric power source to create the diode effect other than the current flowing through the length of superconducting material 200 in which the diode effect is produced.

In other forms of the technology, the magnetic field generator 300 may comprise other types of magnets, for example electromagnets. The electromagnets may be positioned in similar positions and orientations to those described forms of the technology using permanent magnets. Forms of the technology in which the applied magnetic field is generated by electromagnets may be considered to be active electrical devices since the electromagnets may use an electric power source to supply current to the electromagnet to create the diode effect in addition to the current flowing through the length of superconducting material 200 in which the diode effect is produced.

### 6.2.6.1.2. Experimental Results/Simulations—Permanent Magnets

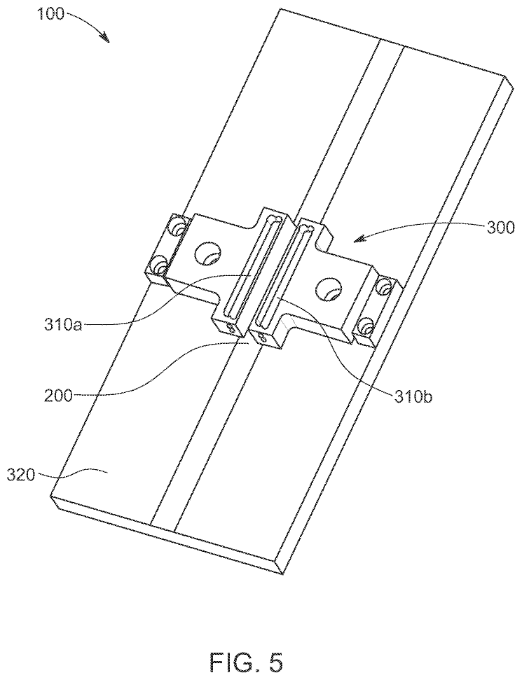

FIG. 5 is a schematic illustration of an electrical device 100 according to one form of the technology similar to the arrangement of FIG. 3. This setup was used to test the electrical device experimentally. The electrical device 100 of FIG. 5, which will be referred to as a diode in the following description, comprises two opposing neodymium bar magnets 310a, 310b to produce a static applied magnetic field on the length of superconducting material 200 in the form of HTS tape. The magnets are mounted to a G10 base 320. The aim of this experiment was to find the optimal position for the magnets in order to maximise the diodicity. To facilitate this, the rig shown in FIG. 5 was designed and manufactured to allow for a reasonable amount of freedom in the position of the magnets in both the x and y directions. The position of the magnets could be selected by inserting 1:5 mm thick G10 spacers in certain positions. To adjust the horizontal position, the spacers were placed between the magnet holder and an aluminium end stop. The vertical position was changed by placing the spacers underneath the magnet in the holder. Thinner spacers could alternatively be used.

For the purposes of the experiment, the sample HTS tape was etched to reduce the critical current of the HTS tape in a specific region. Normally when applying a magnetic field to a specific region, the critical current of that region would be reduced, making the etching redundant. However, in the forward bias direction it is possible that the critical current could be increased beyond that of the rest of the tape, meaning that a quench could occur somewhere else. Thus etching was used to ensure that this would not happen. The electric field of the tape was measured using voltage taps placed on either side of the etched region. These voltage taps were connected to a nano voltmeter which could be monitored and sampled using a LabVIEW program.

The diode was subjected to multiple full forward and reverse bias cycles to test whether this would have an effect on the diodicity.

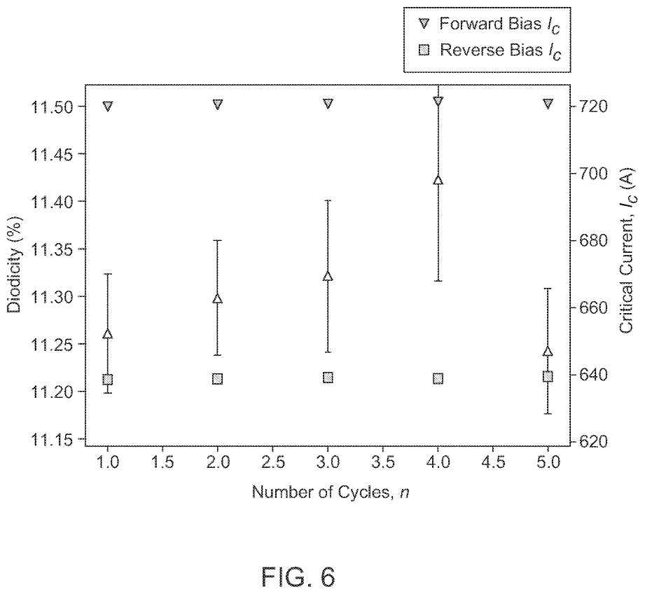

The experimental results are shown in FIG. 6, which is a graph showing the forward and reverse critical currents and the diodicity of the diode arrangement of FIG. 5. Current was cycled through the diode five times to yield the illustrated results. The average diodicity was 11.31±0.03%.

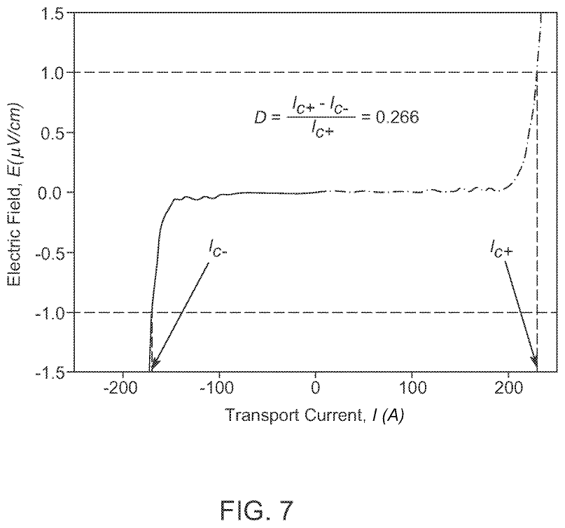

The results of another experimental test on a prototype built based on the arrangement shown in FIG. 3 is shown in FIG. 7. In this version, the diodicity was calculated as 0.266 (or 26.6%).

The position of the permanent magnets 310a and 310b can be moved in order to vary the performance of the diode. A desirable position of the magnets, for example to optimise the diodicity of the diode, may be selected through trial and error or by simulating the arrangement and analysing the positions of the magnets that optimise the diodicity. FIG. 8 shows a schematic for a modelling geometry according to one form of the technology. The arrangement of items of electrical device 100, which comprises a length of superconducting material 200 and two permanent magnets 310a and 310b, modelled in the analysis is similar to that shown in FIG. 3. The x and y variables are the distance of the centre of one of the permanent magnets from the centre of the length of superconducting material 200 in the x and y directions respectively. The centre of the other magnet is positioned at (−x, y).

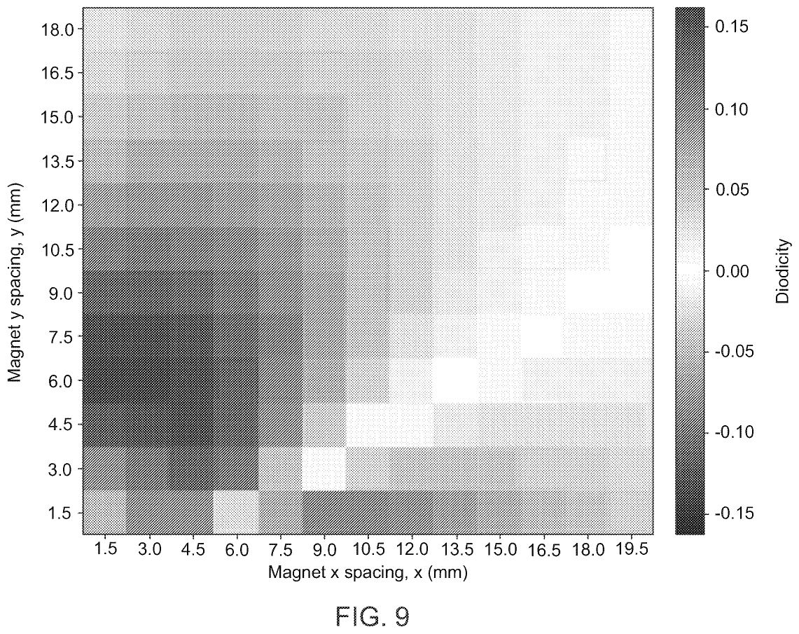

The results of one example of a simulation are shown in FIG. 9. In FIG. 9, the normalised diodicity is shown by the scale on the right side of the figure. This simulation indicates that the diodicity increases with decreasing x and increasing y, although for low values of x the diodicity decreases with increasing y above an optimum value. Other simulations have indicated that relatively high diodicity may be achieved for relatively low values of x irrespective of the value of y. These results indicate that a higher diodicity may be able to be achieved the closer the permanent magnets 310a and 310b are positioned together, although there may be an optimum separation distance between the permanent magnets for any given value of y. In some forms, these distances may be able to be determined by experimentation.

Simulations performed indicated that a diode inversion occurs for certain positions of the permanent magnets 310a and 310b in an arrangement such as shown in FIGS. 3 and 8. This can be seen in the negative values for diodicity in the bottom right hand side of the chart in FIG. 9. That is, for relatively high values of x, and/or for relatively low values of y, the bias of the diode may be reversed. This bias reversal may occur, for a given spacing of the magnets from the length of superconducting material 200 in the y-direction, when the magnets are placed more than a threshold distance apart.

This reversal of the bias is demonstrated by FIGS. 10A and 10B, which are field line plots for two exemplary arrangements of the permanent magnets 310a and 310b compared to the length of superconducting material 200 when in the arrangement of FIGS. 3 and 8. In these figures, the positive and negative signs are indicative of the direction of the net magnetic field in the y-direction, i.e. up and down the page, at the relevant point, and the density of the signs is roughly indicative of the strength of the magnetic field in the relevant region. The field within the oval around the length of superconducting material 200 has been amplified to more clearly show the nature of the field in this region. It can be seen that the direction of the net magnetic field at each edge of the length of superconducting material 200 in FIG. 10A is opposite to that in FIG. 10B. The arrangement of the diode in FIG. 10A has an opposite bias to the arrangement of the diode in FIG. 10B, where the permanent magnets 310a and 310b are positioned further apart (i.e. larger x value) and closer to the plane of the length of superconducting material 200 (i.e. smaller y value). The y component of the applied magnetic field produced by a permanent magnet points in the opposite direction at the sides of the magnet when compared to the field at the poles. This means that, when the magnets are placed relatively high above the length of superconducting material 200, the field at the length of superconducting material 200 is mostly from the poles from the magnets. When the magnets are lowered such that they are almost either side of the length of superconducting material 200, the field at the side of the magnets dominates, inverting the y component of the field at the tape. This in turn flips the polarity of the diode resulting in the observed negative diodicities in the arrangement of FIG. 10B compared to that of FIG. 10A.

In one form of the technology the electrical device 100 may comprise a magnet position mechanism configured to controllably move the position of the permanent magnets 310a and 310b in order to select a desired orientation of the forward and reverse bias directions.

### 6.2.6.1.3. Additional Superconductor

In other forms of the technology, the electrical device 100 comprises a magnetic field generator 300 comprising another length of superconducting material 330 to generate the applied magnetic field. The second length of superconducting material 330 generates a magnetic field when a current flows through it, as occurs when any conductor carries a current, as explained earlier.

In exemplary forms, the second length of superconducting material 330 is positioned proximate the first length of superconducting material 200. The second length of superconducting material 330 may be positioned such that the first length of superconducting material 200 is subject to an applied magnetic field of a similar strength, e.g. a similar order of magnitude, to the self-magnetic field generated by the first length of superconducting material 200 when current flows through it. The first and second lengths of superconducting material are electrically isolated from each other in these forms.

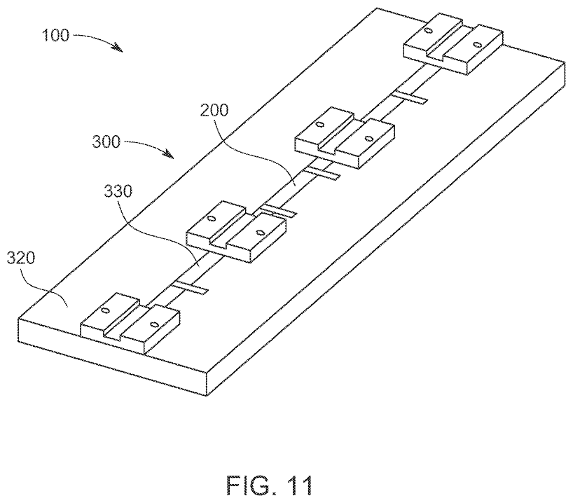

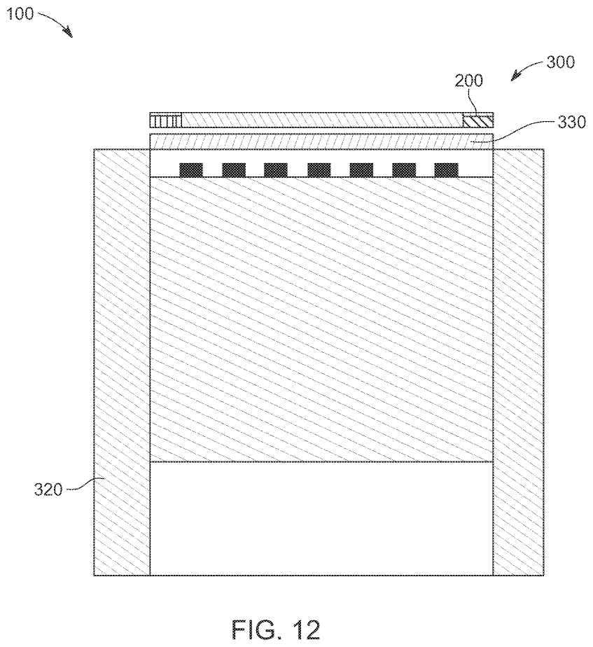

An exemplary form of electrical device 100 with an arrangement of this type is shown in FIGS. 11 and 12, which are perspective and end cross-sectional views of the electrical device 100 respectively. In the example form of FIGS. 11 and 12, the second length of superconducting material 330 is oriented substantially parallel to the first length of superconducting material 200. For example, the lengths of superconducting material may both be in the form of tape, e.g. HTS tape, with the faces of the two tapes being parallel to each other. In addition, the lengths of the tapes may be oriented parallel to each other. The two tapes may be placed close together, e.g. with the distance between the faces of the tapes being significantly less than the width of either tape.

The Hall probe array positioned under the second length of superconducting material 330 is shown in FIG. 12 to demonstrate an exemplary arrangement that may be used for the purposes of experimentally confirming the operation of the electrical device 100, and the array may be omitted from the electrical device 100 in normal operation.

In one experiment using the exemplary form illustrated in FIGS. 11 and 12, a diodicity of 10.85±0.04% was achieved with a forward bias current on the order of hundreds of amperes. In the course of experiments, the behaviour of the magnetic field was analysed and found to be in line with the theory described earlier. Persisting issues with the power supplies and the Hall probe array did diminish the quality of the results and therefore the magnitudes of diodicity obtained, however the data still showed strong trends that backed up the functionality of the device.

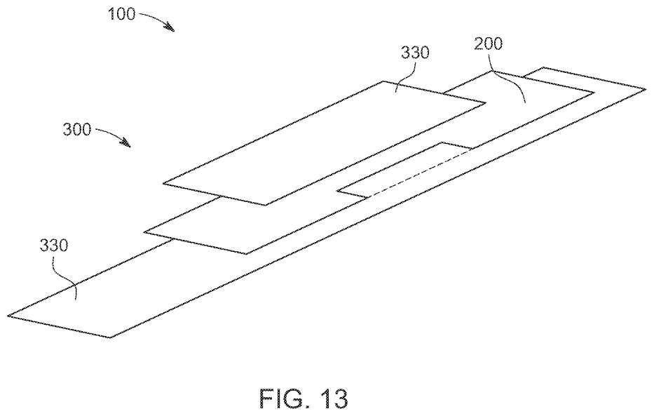

Another exemplary form of the technology is illustrated in FIG. 13. In this form, the electrical device 100 comprises a magnetic field generator 300 that comprises two lengths of superconducting material 330, for example HTS tapes. One of the tapes is positioned on one side of the length of superconducting material 200 in which the diode effect is to be created, similar to as described in relation to the form of FIGS. 11 and 12, while the other tape is positioned on the opposite side of the length of superconducting material 200 in proximity thereto, but electrically isolated from it. The two tapes may be arranged substantially parallel to each other and/or to the length of superconducting material 200.

In use, current is passed through each of the HTS tapes in order for each to generate a magnetic field, and the combination of these two fields is the applied magnetic field of the magnetic field generator 300. In certain forms, a DC current is passed through each of the HTS tapes in the same direction, for example the direction indicated by the arrow I_{gate} in FIG. 13. The field strength profile of the applied magnetic field of the magnetic field generator 300 of the form shown in FIG. 13 in the forward and reverse bias configurations is similar to that shown in FIGS. 4A and 4B.

Experiments with an electrical device 100 comprising such a magnetic field generator 300 suggest that this configuration may enable higher diodicities to be achieved than forms in which the magnetic field generator 300 comprises a single HTS tape in proximity to the length of superconducting material 200. For example, in one exemplary such device, a diodicity of 15.6% was recorded.

The electrical devices 100 according to the forms of the technology illustrated in FIGS. 11 to 13 may be considered to be active devices since an additional power source is used to supply current to the second lengths of superconducting material 330 (i.e. in addition to the supply of current to the length of superconducting material 200). In certain forms, the lengths of superconducting material 330 are supplied with power from a direct current power source, while the length of superconducting material 200 may be supplied an alternating current (for example to rectify the AC). The direction of the bias of the diode effect in electrical device 100 may be adjusted by control of the direction of current flow through the one or more second length of superconducting material 330. When the direction in which current flows through the second length of superconducting material 330 is changed to an opposite direction, the directions of current flow through the length of superconducting material 200 that corresponds to the forward and reverse bias directions are swapped. This effect may be utilised in some forms of the technology, for example, the electrical device 100 may comprise a current control mechanism configured to selectively control the direction of current flow through the one or more lengths of superconducting material 330. Any suitable current control mechanism may be used. In addition, the current control mechanism may be configured to selectively stop the supply of current to the one or more lengths of superconducting material 330. In these forms, the diode effect of the electrical device 100 may be selectively turned off and turned on and, when turned on, the direction of the bias may be controlled, i.e. the electrical device 100 may act as a controllable direction-reversible diode. The electrical device 100 in these forms may also be considered to act as, or analogously to, a transistor.

### 6.2.6.2. Second Magnetic Field Generator

In certain forms of the technology, the electrical device 100 comprises a second magnetic field generator 500 in addition to the magnetic field generator 300, which may be referred to as the first magnetic field generator 300 to distinguish the two magnetic field generators. In use, each of the first magnetic field generator 300 and the second magnetic field generator 500 are configured and arranged to apply a magnetic field to the length of superconducting material 200. The magnetic fields generated by the first and second magnetic field generators may be referred to as the first magnetic field and the second magnetic field respectively.

In these forms of the technology, a diode effect may be created in the length of superconducting material 200 because the combined effect of the two magnetic fields on the length of superconducting material 200 differs when current flows through the length of superconducting material 200 in one direction compared to the combined effect of the two magnetic fields when current flows through the length of superconducting material 200 in the opposite direction.

Examples of such forms of the technology are described below. It should be appreciated that, in these forms, in addition to the magnetic fields produced by the first and second magnetic field generators, the length of superconducting material 200 also produces a self-magnetic field itself, as described in relation to other forms of the technology earlier. In some cases, the magnitude and effect of this self-magnetic field may be negligible compared to the magnitude and effect of each of the magnetic fields generated by the first and second magnetic field generators. Consequently, the self-magnetic field may be able to be largely disregarded in some forms of the technology in which there are two other magnetic fields interacting to produce the net magnetic field acting on the length of superconducting material 200.

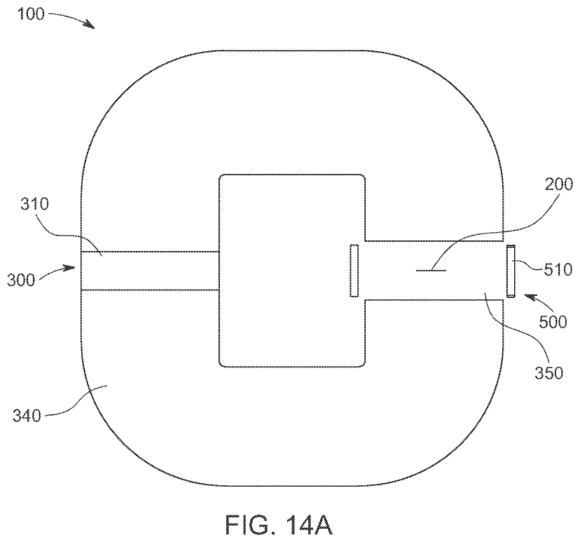

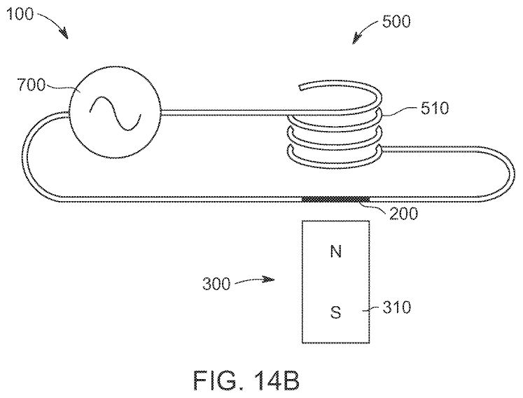

FIG. 14A is a schematic illustration of an electrical device 100 according to one form of the technology. The electrical device 100 shown in FIG. 14A comprises a length of superconducting material 200, which may be in the form of an HTS tape. The length of superconducting material 200 extends in and out of the page. In use, a current may be passed in either direction along the length of superconducting material 200.

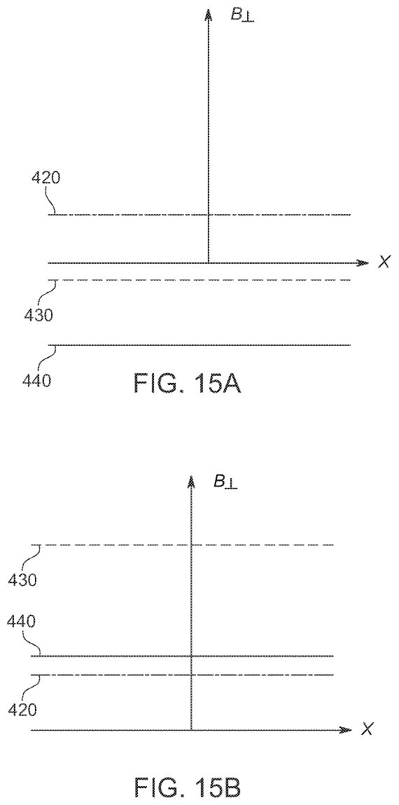

The electrical device 100 of FIG. 14A comprises a first magnetic field generator 300. The first magnetic field generator 300 comprises a permanent magnet 310 positioned where the first magnetic field it generates is applied to the length of superconducting material 200. In the exemplary form of FIG. 14A this is achieved by using a magnetic core 340, for example any of the forms of magnetic core 340 described earlier. The magnetic core 340 channels the first magnetic field towards the length of superconducting material 200. For example, the magnetic core 340 may comprise one or more magnetic core portions arranged to form a gap 350 between two ends of the magnetic core portions. The length of superconducting material 200 may be placed in the gap 350. This arrangement may have the effect of generating a substantially uniform first magnetic field between the ends of the magnetic core portions. The variation of the strength of the first magnetic field on the length of superconducting material 200 in the x-direction (being the distance across the width of the length of superconducting material 200, i.e. the left-right direction in FIG. 14A) is shown in FIGS. 15A and 15B by line 420. The magnitude of the magnetic field is substantially similar for all x across the width of the length of superconducting material 200. The direction of the first magnetic field is dependent on the polarity of the permanent magnet 310 but is shown as being positive in FIGS. 15A and 15B.

In the form shown, the magnetic core 340 is formed from two portions with one end of each magnetic core portion forming an edge of gap 540 and the other end of each of the magnetic core portions abutting permanent magnet 310. The magnetic core portions may be substantially U-shaped or C-shaped, for example. In other forms, the magnetic core 340 may be a different shape, and other examples of suitable magnetic cores are discussed above.

In alternative forms, the first magnetic field generator 300 may comprise another form of magnetic field generator, for example an electromagnet. For example, a coil of conductor (e.g. superconductor) may be wound around the magnetic core 340 in order to induce the first magnetic field in the core when a current is passed through the conductor. In some alternative forms, the first magnetic field generator 300 may comprise no magnetic core 340.

The form of electrical device 100 shown in FIG. 14A also comprises a second magnetic field generator 500. The second magnetic field generator 500 is also positioned where the magnetic field it generates, i.e. the second magnetic field, is applied to the length of superconducting material 200. The second magnetic field generator 500 comprises a coil 510 of conductor through which a current can pass. When a current passes through the coil 510, the second magnetic field is produced. The length of superconducting material 200 may be placed relative to the coil 510 so that the second magnetic field is applied to it. For example, the length of superconducting material 200 may be positioned within the coil 510. In the form of electrical device 100 shown in FIG. 14A, the coil 510 is positioned around the gap 350 defined by the magnetic core 340. In some forms, at least a part of the coil 510 may be wound around the magnetic core 340, including all of the coil 510 being wound around the magnetic core 340. The effect of positioning the coil 510 in this way is that the second magnetic field is also substantially uniform across the width of the length of superconducting material 200. The magnetic field lines of the second magnetic field may also be substantially parallel to those of the first magnetic field. The direction (i.e. polarity) of the second magnetic field may be determined by the direction in which current flows through the coil 510.

As is shown in the circuit diagram illustration of FIG. 14B, which shows schematically the same form of electrical device 100 as is shown in FIG. 14A connected to an alternating current power source 700, the conductor that forms the coil 510 may be a length of conductor, e.g. a length of superconducting material, that is joined in series to the length of superconducting material 200 in which the diode effect is created. Consequently, the direction of current flow through the length of superconducting material 200 in which the diode effect is created is linked to the direction of current flow through the coil 510, and consequently linked to the direction of the second magnetic field acting on the length of superconducting material 200. It is this link that is used to create an asymmetry in the net magnetic field on the length of superconducting material 200 dependent on the direction of current flow through the length of superconducting material 200. Also, since it is the same current passing through the coil 510 that generates the second magnetic field as the current through the length of conducting material 200 that is subject to the diode effect, no additional electric power source to create the diode effect other than the current flowing through the length of superconducting material 200 in which the diode effect is produced, and this form of the technology may be considered a passive device.

FIG. 15A is a graph showing the variation of the strength of the magnetic fields on the length of superconducting material 200 of FIGS. 14A and 14B when current flows through the length of superconducting material 200 in one direction. In this graph, line 420 is the applied first magnetic field due to the first magnetic field generator 300 (i.e. the permanent magnet 310 in FIGS. 14A and 14B), line 440 is the applied second magnetic field due to the second magnetic field generator 500 (i.e. the coil 510 when it carries current) and line 430 is the net magnetic field (i.e. the sum of the first and second magnetic fields). The same magnetic field strengths are shown in FIG. 15B when current flows through the length of superconducting material 200 in the opposite direction.

The situation shown in FIG. 15A is the forward bias configuration of the electrical device 100. In this configuration, the first magnetic field and the second magnetic field act in opposing directions. Consequently, when combined to produce the net magnetic field, their magnitudes cancel and the net magnetic field is relatively low in magnitude. For example, if the first and second magnetic fields are of similar absolute magnitudes, the net magnetic field may be close to, or substantially, zero. In this configuration, there is relatively little suppression of the critical current of the length of superconducting material 200 due to the applied net magnetic field. Consequently, the critical current of the length of superconducting material 200 is relatively high.

The situation shown in FIG. 15B is the reverse bias configuration of the electrical device 100. In this configuration, the current flows through the coil 510 in the opposite direction to that of the forward bias confirmation, and the first magnetic field and the second magnetic field act in the same direction. Consequently, when combined to produce the net magnetic field, their magnitudes add and the net magnetic field is relatively high in magnitude. In this configuration, there is a greater amount of suppression of the critical current of the length of superconducting material 200 due to the applied net magnetic field. Consequently, the critical current of the length of superconducting material 200 is relatively low compared to in the forward bias configuration.

This difference between the critical current of the length of superconducting material 200 between the forward and reverse bias configurations, dependent on the direction of current flow through the length of superconducting material 200, creates the diode effect in the length of superconducting material 200 and a value of diodicity as defined earlier.

It will be appreciated that, in configuring a suitable electrical device 100 to operate in the manner described here, the various parameters of the device that affect the magnetic field strength and direction may be selected to achieve relative first and second magnetic field strengths similar to those shown in FIGS. 14A and 14B. Furthermore, the parameters may be selected so that the magnitude of the net magnetic field applied to the length of superconducting material 200 may maintain the length of superconducting material 200 in a superconducting state in at least the forward bias configuration and, in some forms, also in the reverse bias configuration, for the desired magnitudes of operating currents. In some forms, the electrical device 100 is configured so that the net magnetic field strength applied to the length of superconducting material 200 in the forward bias configuration (as shown in FIG. 15A) is substantially zero, i.e. the magnitude of the first and second magnetic fields are equal, although they act in opposite directions.

In certain forms of the technology, the length of superconducting material 200 in which the diode effect is created may have a lower critical current than adjacent portions of superconducting material joined in series to the length of superconducting material 200, for example including the length of superconducting material 330 that forms the coil 510 in the exemplary form of FIG. 14A. A superconductor will move into a higher resistance state if the current density approaches, is similar to, or exceeds the critical current density, for example the superconductor will become non-superconducting if the current density exceeds the critical current density. In the operation of the electrical device 100 as a diode, it may be desired for the critical current density to be approached, substantially equalled or exceeded only in the length of superconducting material 200 in which the diode effect is to be produced, and not in other parts of the superconducting circuit. This effect may be achieved, in certain forms, for example, by the length of superconducting material 200 in which the diode effect is created having a smaller cross-sectional area than adjacent portions of superconducting material joined in series to the length of superconducting material 200. The current density through a length of superconducting material is dependent on the magnitude of the current flowing through the material and also on the cross-sectional area of the length of superconducting material. If the length of superconducting material 200 has a smaller cross-sectional area, e.g. a narrower width in the case of HTS tape, than other parts of the superconducting circuit, the critical current density will be achieved in the length of superconducting material 200 before any other part of the circuit. The cross-sectional area difference between the adjacent portions of the superconducting material may be a useful way to achieve the difference in critical currents between these portions where the portions are formed from a single length of superconducting material. In other forms, the difference may be achieved in other ways, for example by using different superconducting materials for the two portions.

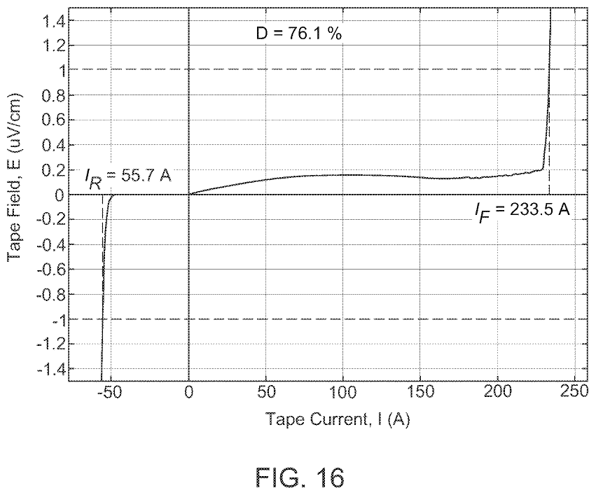

FIG. 16 is a graph showing current against electric field for a length of Rare Earth BaCuO coated conductor superconducting material 200 according to computer modelling of the form of the technology shown in FIG. 14A. In the exemplary modelling, the critical current in the forward bias configuration is 233.5 A and the critical current in the reverse bias configuration is 55.7 A. This means the diodicity is 76.1%.

The length of superconducting material 200 in the electrical device 100 of FIG. 14A may be subject to a change in net magnetic field across its full width between the forward and reverse bias configurations. This may result in larger diodicities than other forms of the technology, such as the electrical device of FIG. 3, which only experiences a change in net magnetic field in edge regions of the length of superconducting material.

In some forms, the coil 510 in the form of electrical device 100 shown in FIG. 14A may possess sufficient inductance to have an impact on the operation of the device. This may impact, for example, the frequency response of the electrical device 100.

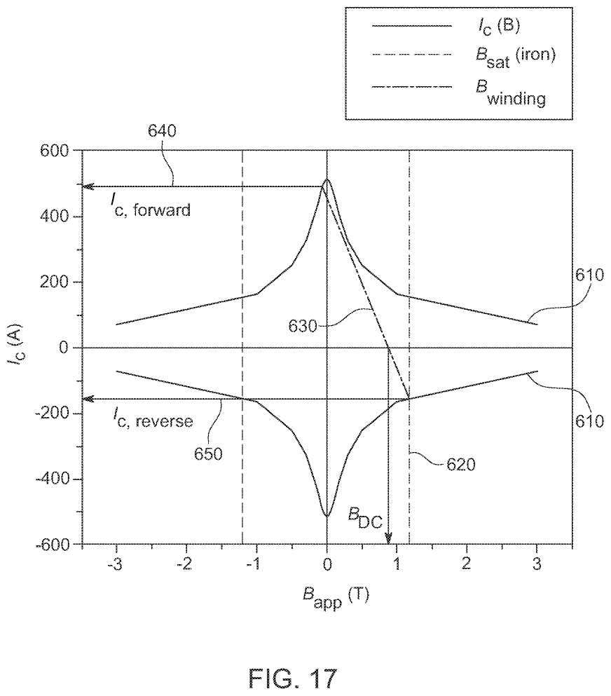

Through selection of certain parameters of the electrical device 100 according to the form of the technology shown in FIG. 14A, it is possible to alter the diodicity produced. In some forms, it may be possible to tune these parameters to increase the diodicity, and perhaps even substantially optimise it. FIG. 17 is a graph showing the relationship between certain parameters in an electrical device 100 according to the form of the technology shown in FIG. 14A. Line 610 represents the critical current against the applied external perpendicular magnetic field for an exemplary superconducting material that may be used to form the length of superconducting material 200. This line illustrates the suppression of the critical current as the absolute magnitude of the applied field increases. Lines 620 illustrate the saturation field of the material used to form the magnetic core, for example iron may have a saturation field of approximately 1.2 T.

The line 630 indicates the variation of the transport current through the length of superconducting material 200 and the coil 510 (vertical axis) with the value of the second magnetic field generated by the second magnetic field generator 500, e.g. the coil 510 of superconducting material. The line 630 is linear and, in the case of the second magnetic field generator 500 comprising a coil 510, its gradient is a function of the number of turns of superconductor in coil 510. When there is no current passing through the coil 510, there is no second magnetic field and therefore the intersection of the line 630 with the horizontal axis (indicating the value of the net applied magnetic field) indicates the magnitude of the first magnetic field generated by the first magnetic field generator 300, i.e. the permanent magnet 310 and magnetic core 340 in the exemplary form of FIG. 14A.

When the electrical device 100 is forward-biased, the current flows through the coil 510 in a direction whereby the second magnetic field produced by the coil 510 opposes the first magnetic field produced by the permanent magnet 310. This state is represented by the upper intersection of the line 630 with the line 610, i.e. the value of the critical current indicated by the line 640. When the electrical device 100 is reverse-biased, the current flows through the coil 510 in the opposite direction whereby the second magnetic field produced by the coil 510 adds to the first magnetic field produced by the permanent magnet 310. This state is represented by the lower intersection of the line 630 with the line 610, i.e. the value of the critical current indicated by the line 650. In forms of the technology in which the electrical device 100 comprises a magnetic core 340, the lower intersection of the line 630 with the line 610 occurs at the saturation field of the magnetic core since the line 630 would no longer be linear for higher field strengths. This limitation does not apply in certain forms of the technology in which the electrical device does not comprise a magnetic core 340.

The diodicity of the electrical device 100 is based on the relative difference between the forward and reverse bias critical currents, as per the formula above. Parameters of the electrical device 100 may be selected to produce a desired diodicity. In particular the electrical device 100 may be able to be designed to maximise the diodicity using the information represented in FIG. 17. For example, the coil 510 may be able to be designed such that it has an appropriate number of coils so that the gradient of line 630 means that the difference between the upper and lower intersections is maximised, thus maximising the diodicity of the electrical device 100. In certain forms, it may be found that the maximum (or near maximum) diodicity occurs when the electrical device 100 is configured so that the line 630 is substantially tangent to the line 610. Since line 610 represents the critical current of the length of superconducting material 200, making line 630 tangent to line 610 represents taking the configuration of the electrical device 100 to the maximum possible currents without exceeding the critical current and losing the superconducting state.

Another design consideration is the trade-off between the self-inductance of the coil 510 and the diodicity. Reducing the self-inductance of the coil 510 may be desired, but doing so may also reduce the diodicity of the electrical device 100. The desired balance may be identified through experiment for given parameters and dependent on the application of the electrical device 100.

### 6.3. Other Remarks

Unless the context clearly requires otherwise, throughout the description and the claims, the words “comprise”, “comprising”, and the like, are to be construed in an inclusive sense as opposed to an exclusive or exhaustive sense, that is to say, in the sense of “including, but not limited to”.

The entire disclosures of all applications, patents and publications cited above and below, if any, are herein incorporated by reference.

Reference to any prior art in this specification is not, and should not be taken as, an acknowledgement or any form of suggestion that that prior art forms part of the common general knowledge in the field of endeavour in any country in the world.

The technology may also be said broadly to consist in the parts, elements and features referred to or indicated in the specification of the application, individually or collectively, in any or all combinations of two or more of said parts, elements or features.

Where in the foregoing description reference has been made to integers or components having known equivalents thereof, those integers are herein incorporated as if individually set forth.

It should be noted that various changes and modifications to the presently preferred embodiments described herein will be apparent to those skilled in the art. Such changes and modifications may be made without departing from the spirit and scope of the technology and without diminishing its attendant advantages. It is therefore intended that such changes and modifications be included within the present technology.

1. An electrical device comprising:
a length of superconducting material comprising two substantially parallel opposed faces; and
a magnetic field generator comprising two permanent magnets positioned on the same side of the length of superconducting material, wherein polar axes of the two permanent magnets are arranged substantially anti-parallel to each other, wherein the polar axes of the two permanent magnets are oriented substantially perpendicular to the faces of the length of superconducting material,
wherein the magnetic field generator is configured and arranged to apply an applied magnetic field to the length of superconducting material such that, when a first current flows in the length of superconducting material in a first direction, the length of superconducting material has a first critical current, and, when a second current flows in the length of superconducting material in a second direction, the second direction being opposite to the first direction, the length of superconducting material has a second critical current, the first critical current being substantially greater than the second critical current.

2. An electrical device as claimed in 1, wherein the length of superconducting material generates a self-magnetic field when current flows through the length of superconducting material, wherein the self-magnetic field and the applied magnetic field produce a net magnetic field, and wherein the magnetic field generator is configured and arranged such that the net magnetic field has a substantially lower magnitude when the first current flows in the length of superconducting material in the first direction compared to when the second current flows in the length of superconducting material in the second direction.

3. An electrical device as claimed in claim 2, wherein the magnetic field generator is configured and arranged such that the applied magnetic field is similar to the self-magnetic field when current flows through the length of superconducting material in the first direction.

4. An electrical device as claimed in claim 1, wherein the two permanent magnets are positioned equidistant from the length of superconducting material.

5. An electrical device as claimed in claim 1, wherein the length of superconducting material comprises a length, a width and a depth, wherein the depth is the distance between the two substantially parallel opposed faces, wherein the length is significantly larger than the width, and the width is significantly larger than the depth.

6. An electrical device as claimed in claim 1, wherein the two permanent magnets are positioned in substantial alignment along the length of the length of superconducting material.

7. An electrical device as claimed in claim 1, wherein both permanent magnets are displaced from the length of superconducting material by substantially the same distance in a direction perpendicular to the faces of the length of superconducting material.

8. An electrical device as claimed in any claim 1, wherein the two permanent magnets are separated by a spacing in a direction parallel to the width of the length of superconducting material, wherein the spacing is greater than the width of the length of superconducting material.

9. An electrical device as claimed in claim 1, wherein the magnetic field generator comprises third and fourth permanent magnets positioned on the opposite side of the length of superconducting material from the two permanent magnets.

10. An electrical device comprising:
a length of superconducting material;
a first magnetic field generator configured and arranged to apply a first applied magnetic field to the length of superconducting material;
a second magnetic field generator configured and arranged to apply a second applied magnetic field to the length of superconducting material,
wherein the first applied magnetic field and the second applied magnetic field produce a net magnetic field, wherein the first and second magnetic field generators are configured and arranged such that, when a first current flows in the length of superconducting material in a first direction, the net magnetic field has a first magnitude and the length of superconducting material has a first critical current, and, when a second current flows in the length of superconducting material in a second direction, the second direction being opposite to the first direction, the net magnetic field has a second magnitude and the length of superconducting material has a second critical current,
wherein the first magnitude is substantially lower than the second magnitude, and the first critical current is substantially greater than the second critical current.

11. An electrical device as claimed in claim 10, wherein the first magnetic field generator comprises a magnetic core formed from a material having a high magnetic permeability, wherein the magnetic core is positioned to channel the applied magnetic field towards the length of superconducting material.

12. An electrical device as claimed in claim 11, wherein the magnetic core comprises a gap and the length of superconducting material is positioned in the gap.

13. An electrical device as claimed in claim 1, wherein the length of superconducting material is a first length of superconducting material and the electrical device further comprises a second length of superconducting material, the second length of superconducting material being joined in series to the first length of superconducting material, and wherein the second magnetic field generator comprises the second length of superconducting material such that the second applied magnetic field is produced by the second length of superconducting material.

14. An electrical device as claimed in claim 13, wherein the second length of superconducting material is arranged in a coil.

15. An electrical device as claimed in claim 14, wherein the first length of superconducting material is positioned inside the coil.

16. An electrical device as claimed in claim 13, wherein the second length of superconducting material has a higher critical current than the first length of superconducting material.

17. An electrical device as claimed in 16, wherein a cross-sectional area of the first length of superconducting material is less than a cross-sectional area of the second length of superconducting material.
